(19) United States
(12) Patent Application Publication
(10) Pub. No.: US 2011/0169551 A1
(43) Pub. Date: Jul. 14, 2011

(54) TEMPERATURE SENSOR AND METHOD

(76) Inventors: Cornel D. Stanescu, Bucharest (RO); Horia Profeta, Bucharest (RO)

(21) Appl. No.: 12/684,696

(22) Filed: Jan. 8, 2010

(51) Int. Cl. H01L 35/00

(52) U.S. Cl. 327/512

(57) ABSTRACT

A temperature sensor and a method for sensing temperature. The temperature sensor has a current generator module that generates a voltage (V_{PTAT}) that is proportional to absolute temperature at an output terminal and a voltage (V_{CTAT}) that is complementary to absolute temperature at another output terminal. A buffer stage has an input terminal coupled for receiving the voltage that is complementary to absolute temperature. An output terminal of the buffer stage is coupled to an input terminal of an amplifier stage. The voltage that is proportional to absolute temperature is input to another input terminal of the amplifier stage. The amplifier stage generates an output voltage from the voltages that are proportional to absolute temperature and complementary to absolute temperature.

### TECHNICAL FIELD

The present invention relates, in general, to integrated circuits and, more particularly, to temperature sensors.

### BACKGROUND

Temperature sensors are used in a variety circuits including, but not limited to measuring the temperature of semiconductor chips that include circuits such as microprocessors, voltage regulators, digital-to-analog converters, digital filters, etc. Analog temperature sensors typically generate an output voltage that increases with increasing temperature, where the temperature coefficient may be about +10 millivolts per degree Celsius and a DC offset voltage may be about 500 mV, allowing negative temperature measurements down to −40 degrees Celsius. A drawback with temperature sensors having temperature coefficients and DC offset voltages in this range is that they use high minimum supply voltages which are unsuitable for portable applications such as, for example, laptop computers, cellular phones, portable digital assistants, or the like. These types of temperature sensors are also unsuitable for nonportable applications because they are inefficient and waste power.

Accordingly, it would be advantageous to have a temperature sensor and a method for sensing temperature capable of having a controlled temperature coefficient and capable of operating at low supply voltage levels. It would be of further advantage for the temperature sensor and method to be cost efficient to implement.

### BRIEF DESCRIPTION OF THE DRAWINGS

The present invention will be better understood from a reading of the following detailed description, taken in conjunction with the accompanying drawing figures, in which like reference characters designate like elements and in which:

FIG. 1 is a circuit schematic of a temperature sensor in accordance with an embodiment of the present invention; and

FIG. 2 is a plot of voltages generated within the temperature sensor of FIG. 1.

### DETAILED DESCRIPTION

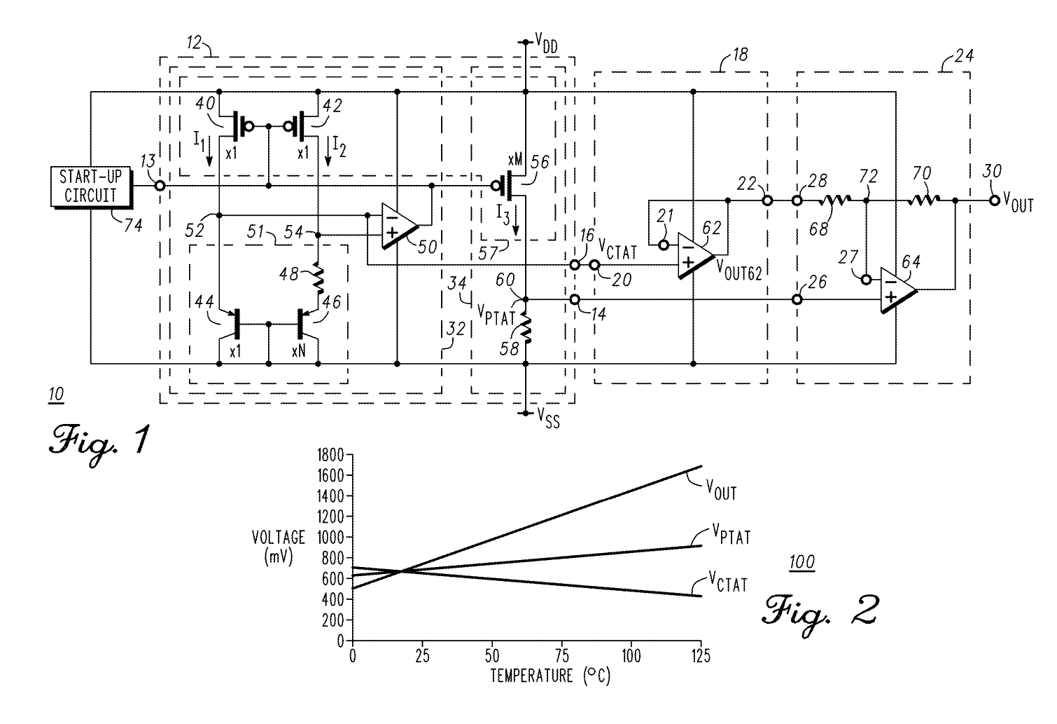

FIG. 1 is a circuit schematic of a temperature sensor 10 in accordance with an embodiment of the present invention. Temperature sensor 10 may be manufactured as a monolithically integrated circuit. As an example, temperature sensor 10 is a centigrade or Celsius temperature sensor. What is shown in FIG. 1 is a current generator module 12 suitable for generating a voltage at an output terminal or node 14 that is proportional to absolute temperature (V_{PTAT}) and a voltage at an output terminal or node 16 that is complementary to absolute temperature (V_{CTAT}). A buffer stage 18 has an input terminal 20 and an output terminal 22, where input terminal 20 is connected to output terminal 16 for receiving voltage V_{CTAT}. Temperature sensor 10 further includes an amplifier stage 24 having input terminals 26 and 28 and an output terminal 30, where input terminal 26 is connected to output terminal 14 for receiving voltage V_{PTAT} and input terminal 28 is connected to output terminal 22 of buffer stage 18, and where output terminal 30 serves as an output terminal of amplifier stage 24 and temperature sensor 10. By way of example, amplifier stage 24 is a differential amplifier stage.

Current generator module 12 is comprised of a proportional to absolute temperature current generator stage 32 coupled to an output stage 34. More particularly, current generator stage 32 is comprised of P-channel field effect transistors (FETs) 40 and 42 having gate terminals commonly connected together and source terminals commonly connected together. The source terminals are coupled for receiving a source of operating potential such as, for example, V_{DD}. It should be noted that the commonly connected gate terminals form an input terminal or node 13. The drain terminal of P-channel FET 40 is connected to an emitter terminal of a PNP bipolar transistor 44 and the drain terminal of P-channel FET 42 is connected to a terminal of an impedance 48. By way of example, impedance 48 is a resistor. The other terminal of resistor 48 is connected to the emitter terminal of PNP bipolar transistor 46. The base terminals of PNP bipolar transistors 44 and 46 are commonly connected together and to the collector terminals of PNP bipolar transistors 44 and 46. Thus, PNP bipolar transistors 44 and 46 are configured as diodes. Transistor 46 has an emitter area that is N times larger than the emitter area of transistor 44. The collector and base terminals of PNP bipolar transistors 44 and 46 are coupled for receiving a source of operating potential such as V_{SS}. By way of example, source of operating potential V_{SS} is at a ground potential. PNP bipolar transistors 44 and 46 and impedance 48 cooperate to form a delta base-emitter voltage (ΔV_{BE}) generator circuit 51 having input nodes 52 and 54.

Proportional to absolute temperature generator stage 32 of current generator module 12 further includes an error amplifier 50 having an inverting input terminal connected to the drain and emitter terminals of P-channel FET 40 and PNP bipolar transistor 44, respectively, a noninverting input terminal connected to the drain terminal of P-channel FET 42 and to the terminal of resistor 48 that is connected to the drain terminal of P-channel FET 42, and an output terminal connected to the gate terminals of P-channel field effect transistors 40 and 42. The commonly connected drain terminal of P-channel FET 40, emitter terminal of PNP bipolar transistor 44, and inverting input terminal of error amplifier 50 form node 52 that may serve as output terminal 16 of current generator module 12. The noninverting input terminal of error amplifier 50 is connected to the drain terminal of P-channel FET 42 and to the terminal of resistor 48 that is connected to the drain terminal of P-channel FET 42 form node 54.

Output stage 34 includes a P-channel FET 56 having a source terminal connected to the source terminals of P-channel FETs 40 and 42, a gate terminal connected to the output terminal of error amplifier 50 and to the gate terminals of P-channel FETs 40 and 42, and a drain terminal connected to a terminal of an impedance 58 to form a node 60. By way of example, impedance 58 is a resistor. The other terminal of resistor 58 is connected to the base terminals and collector terminals of PNP bipolar transistors 44 and 46. It should be noted that FETs 40, 42, and 56 cooperate to form a current mirror 57. By way of example, FETs 40, 42, and 56 are Metal Oxide Semiconductor Field Effect Transistors (MOSFETs).

Buffer stage 18 comprises an amplifier 62 having a noninverting input terminal 20 connected to output terminal 16 and thus to node 52 and an inverting input terminal 21 connected to its output terminal 22. Amplifier 62 may be an operational amplifier, an operational transconductance amplifier, or the like.

Amplifier stage 24 comprises an amplifier 64 having a noninverting input terminal 26 connected to output terminal 14 of current generator module 12, an inverting input terminal 27 coupled to output terminal 22 of buffer stage 18 through an impedance 68, and an output terminal 30 coupled through an impedance 70 to its inverting input terminal 27 and to a terminal of impedance 68 to form a node 72. Amplifier 64 may be an operational amplifier, an operational transconductance amplifier, or the like. By way of example, impedances 68 and 70 are resistors. It should be noted that the noninverting input terminal of amplifier 64 may serve as input terminal 26 of amplifier stage 24 and the output terminal of amplifier 64 may serve as output terminal 30 of temperature sensor 10. An output voltage that appears at the output terminal of amplifier 64 serves as the output voltage of temperature sensor 10 and thus appears at output terminal 30. The output voltage appearing at output terminal 30 is proportional to the temperature in centigrade or Celsius and has a DC offset voltage.

It should be further noted that the source and drain terminals of a FET may be referred to as current carrying electrodes, current conducting electrodes, sources, and drains and the gate terminal of a FET may be referred to as a control electrode, a control terminal, a gate terminal, or a gate. Similarly, the collector and emitter terminals of a bipolar transistor may be referred to as current carrying electrodes, current conducting electrodes, collectors, and emitters and the base terminal of a bipolar transistor may be referred to as a control electrode, a control terminal, a base terminal, or a base.

Although FETs 40, 42, and 56 are shown and described as being P-channel transistors, this is not a limitation of the present invention. Alternatively FETs 40, 42, and 56 can be N-channel FETs. Likewise, transistors 44 and 46 being shown and described as PNP bipolar transistors are not limitations of the present invention. Alternatively, transistors 44 and 46 may be NPN bipolar transistors. It should be noted that FETs and bipolar transistors refer to the types of transistors, whereas the conductivity types of FETs 40, 42, and 56 and bipolar transistors 44 and 46 refer to their majority charge carriers. Thus, an N-channel FET is a type of transistor in which electrons are the majority charge carrier and a P-channel FET is a type of transistor in which holes are the majority charge carrier. An NPN bipolar transistor is a type of transistor in which electrons are the majority charge carrier and a PNP bipolar transistor is a type of transistor in which holes are the majority charge carrier.

By way of example, P-channel FETs 40 and 42 have a normalized area of one, whereas P-channel transistor 56 has an area of M, where M is a multiplier of the areas of P-channel FETs 40 and 42. Similarly, PNP bipolar transistor 44 has a normalized area of one and PNP bipolar transistor 46 has an area of N, where N is a multiplier of the area of PNP bipolar transistor 44. In accordance with this embodiment, if the area of P-channel FETs 40 and 42 is unity, the area of P-channel FET 56 is M times one and if the area of PNP bipolar transistor 44 is unity, the area of PNP bipolar transistor 46 is N times one. It should be further understood that the types of transistors are not limitations of embodiments in accordance with the present invention, i.e., transistors 40, 42, and 56 may be N-channel FETs and transistors 44 and 46 may be NPN bipolar transistors.

Optionally, temperature sensor 10 includes a start-up circuit 74 which places current generator module 12 at a stable operating point when power is applied to temperature sensor 10.

In operation, power is applied to temperature sensor 10 and as discussed above start-up circuit 74 places current generator module 12 at a stable operating point. Start-up circuit 74 places a voltage at input terminal 13 which sets a voltage at the gates of P-channel FETs 40, 42, and 56 and causes currents I₁, I₂, and I₃ to flow from their respective drains. Because P-channel FETs 40 and 42 have substantially the same channel length to width (L/W) ratios and the same gate to source voltages, currents I₁ and I₂ are substantially equal. Although P-channel FET 56 has the same gate to source voltage as P-channel FETs 40 and 42, its length to width ratio is different from those of P-channel FETs 40 and 42 by the factor “M.” Thus, the drain current I₃ of P-channel FET 56 is a multiple of currents I₁ and I₂ by the factor “M,” i.e., I₃=M*I₁=M*I₂. It should be noted that P-channel FETs 40, 42, and 56 have the same gate to source voltage because their gate terminals are electrically connected together and coupled for receiving the same source voltage and their source terminals are electrically connected together and coupled for receiving the same source voltage.

Currents I₁ and I₂ are transmitted to PNP bipolar transistors 44 and 46, respectively. Although the currents flowing to PNP bipolar transistors 44 and 46 are the same, the current densities of PNP bipolar transistors 44 and 46 are different because they have different emitter areas. For example, if the emitter area of PNP bipolar transistor 44 is normalized to one, the emitter area of PNP bipolar transistor 46 is “N,” where “N” is the ratio of the emitter area of PNP bipolar transistor 46 to the emitter area of PNP bipolar transistor 44. Because error amplifier 50 maintains the voltages at nodes 52 and 54 at substantially the same voltage level and PNP bipolar transistors 44 and 46 are configured as diodes having different emitter areas, the voltage V₄₈ across resistor 48 is given by:

V₄₈=ΔV_{BE}=V_{T}*ln(N) Equation 1

where:

V_{T} is the thermal voltage given by k*T/q in which k is Boltzmann's constant, q is the magnitude of electronic charge, and T is absolute temperature in degrees Kelvin; and

N is the ratio of the emitter area of PNP bipolar transistor 46 to the emitter area of PNP bipolar transistor 44.

The voltage at node 60 and hence the voltage at output terminal 14 can be determined from voltage V₄₈ given by Equation 1 in conjunction with Equation 2:

V₆₀=M*ΔV_{BE}*(R₅₈/R₄₈) Equation 2

where:

R₅₈ is the resistance value of resistor 58; and

R₄₈ is the resistance value of resistor 48.

Substituting Equation 1 into Equation 2 yields:

V₆₀=M*V_{T}*ln(N)*(R₅₈/R₄₈) Equation 3

Voltage V₆₀ at output terminal 14 is a voltage that is proportional to absolute temperature V_{PTAT}. It should be noted that the value of resistor 58 can be substantially reduced when the value of M is three or greater.

The voltage at node 52 and hence the voltage at output terminal 16 when operating potential V_{SS} is ground is given by Equation 4 as:

V₅₂=V_{EB44}=V_{T}*ln(I_{C44}/I_{S44}) Equation 4

where:

V_{EB44} is the emitter-base voltage of PNP bipolar transistor 44;

I_{C44} is the collector current of PNP bipolar transistor 44; and

I_{S44} is the emitter-base saturation current of PNP bipolar transistor 44.

Voltage V₅₂ at output terminal 16 is a voltage that is complementary to absolute temperature V_{CTAT}.

Emitter-base voltage V_{EB44}, i.e., voltage V₅₂ when operating potential V_{SS} is at ground potential, which is a voltage that is complementary to absolute temperature, is buffered using an amplifier 62 in a unity gain configuration to inhibit additional current from flowing into or out of node 52. An output voltage V_{OUT62} that is complementary to absolute temperature appears at output terminal 22 and at input terminal 28 of amplifier stage 24. Assuming buffer amplifier 62 and amplifier 64 of amplifier stage 24 are ideal, the output voltage V_{OUT} appearing at output terminal 30 is given by:

V_{OUT}=V_{PTAT}+(V_{PTAT}−V_{CTAT})*(R₇₀/R₆₈) Equation 5

where:
V_{PTAT} is the voltage that is proportional to absolute temperature at terminal 14;
V_{CTAT} is the voltage that is complementary to absolute temperature at terminal 16;
R₇₀ is the resistance value of resistor 70; and
R₆₈ is the resistance value of resistor 68.

It should be noted that there is a temperature T₀ at which output voltage V_{OUT}, voltage V_{PTAT}, and voltage V_{CTAT} are equal at terminals 30, 14, and 16, respectively, i.e., V_{OUT}(T₀)=V_{PTAT}(T₀)=V_{CTAT}(T₀). By way of example, voltage V_{CTAT} is 660 millivolts (mV) at 300 degrees Kelvin (° K) and the temperature coefficient of voltage V_{CTAT} is −2 mV per degree Celsius (° C.). In this example, at temperature T₀ (if T₀ is less than 27° C. or 300° K) voltage V_{CTAT} is given by Equation 6:

V_{PTAT}(T₀)=660 mV+(2 mV/° C.)*(27° C.−T₀) Equation 6

If output voltage V_{OUT} is 500 mV at 0° C. or 273° K) and the temperature coefficient of voltage V_{OUT} is 10 mV/° C., then at temperature T₀ (if T₀ is less than 27° C. or 300° K) voltage V_{OUT}(Tₒ) is given by Equation 7:

V_{OUT}(T₀)=500 mV+(10 mV/° C.)*T₀ Equation 7

Setting voltage V_{PTAT}(T₀) equal to voltage V_{OUT}(T₀) gives a value for temperature T₀ of approximately 17.8° C.

FIG. 2 is a plot 100 of voltages V_{OUT}, V_{PTAT}, and V_{CTAT} versus temperature for a temperature sensor in accordance with embodiments of the present invention. From FIG. 2, voltages V_{CTAT} and V_{PTAT} are less than 950 mV over the temperature range 0° C. to 125° C. Because temperature T₀ is about 17.8° C., voltages V_{CTAT} and V_{PTAT} are also less than 950 mV over the temperature range −40° C. to 125° C.

The minimum supply voltage V_{CC} can be determined using the maximum value between voltages V_{PTAT} and V_{CTAT}, the magnitude of the threshold voltage (V_{THP}) for P-channel FETs used at the inputs of amplifiers 50, 62, and 64, and the overdrive voltage (V_{OVP}) for the P-channel FETs used to bias the input stages of amplifiers 50, 62, and 64. The minimum supply voltage V_{DDMIN} is given by Equation 8:

V_{DDMIN}=MAX{V_{CTAT},V_{PTAT}}+|V_{THP}|+|V_{OVP}|

V_{DDMIN}=0.95V+0.7V+0.15V=1.8V Equation 8

Thus, in accordance with this example the supply voltage can be as low as 1.8V.

Analyzing the slopes of the plots of voltages V_{OUT}, V_{PTAT}, and V_{PTAT} in FIG. 2 indicates that the temperature coefficients of V_{CTAT} and V_{PTAT} are close but not equal to each other. In embodiments in which voltage V_{PTAT} is at least 700 mV, i.e., at least 40 mV higher than voltage V_{CTAT}, the temperature coefficient of voltage V_{PTAT} can be determined from Equation 9:

∂V_{PTAT}/∂T=V_{PTAT}/T=V_{PTAT}(300° K)/300° K.≈700 mV/300° K.≈2.34 mV/° K=2.34 mV/° C. Equation 9

Voltage V_{PTAT} at 300° K is given by Equation 10:

V_{PTAT}(300° K)≈V_{CTAT}(300° K)−2*(27° C.−T₀)*(∂V_{CTAT}/∂T)=660 mV−2*(27° C.−17.8° C.)*(−2 mV/° C.)≈700 mV. Equation 10

The ratio of resistor values for resistors 70 and 68 can be determined from Equation 11:

TC_{OUT}=∂V_{OUT}/∂T=(∂V_{PTAT}/∂T)*(1+R₇₀/R₆₈)−(∂V_{CTAT}/∂T)*(R₇₀/R₆₈)T_{COUT}=10 mV/° C. Equation 11

Thus, the ratio of resistance values R₇₀/R₆₈ equals 1.765.

The ratio can be set by trimming one or both of resistance values R₇₀ and R₆₈.

By now it should be appreciated that a temperature sensor and a method for sensing temperature have been provided. In accordance with embodiments, the temperature sensor generates a voltage that is proportional to absolute temperature and a voltage that is complementary to absolute temperature that are further processed to generate an output voltage that has a low temperature spread and a controlled coefficient of thermal expansion of for example +10 millivolts per degree Celsius over a temperature range of, for example, −40° C. to 125° C., and a DC offset voltage of, for example, 500 mV). The voltage that is complementary to absolute temperature is buffered through a unity gain buffer to generate a buffered voltage V_{OUT62} that is complementary to absolute temperature. Output voltage V_{OUT} is generated from buffered voltage V_{OUT62} at input terminal 28 and the voltage V_{PTAT} that is proportional to absolute temperature at input terminal 26. In generating output voltage V_{OUT}, buffered voltage V_{OUT62} is multiplied by a gain factor that comprises a ratio of the resistance value of resistor 70, R70, to the resistance value of resistor 68, R68. It should be noted that amplifier stage 24 is referred to as a differential amplifier stage because the portion of output voltage V_{OUT} derived from input terminal 28 has a gain factor that comprises the product of the ratio of the resistance value of resistor 70 to the resistance value of resistor 68 and negative one, i.e., −R70/R68 and the portion of output voltage V_{OUT} derived from input terminal 26 is the sum of the ratio of the resistance value of resistor 70 to the resistance value of resistor 68 and one, i.e. 1+R70/R68.

The unity gain buffer and the differential amplifier stage may be configured using P-channel FETs for the input devices of the amplifiers. Thus, the input devices of the unity gain buffer and amplifier 64 may be P-channel FETs configured as a differential pair. Although the supply voltage that can be used with the temperature sensor in accordance with embodiments is low, using the P-channel FETs for the input devices of the unity gain buffer stage and the amplifier 64 further lowers the voltage levels for the supply voltage. The operating parameters of the temperature sensor can be further optimized by trimming resistors that may be present in the differential amplifier stage.

Although specific embodiments have been disclosed herein, it is not intended that the invention be limited to the disclosed embodiments. Those skilled in the art will recognize that modifications and variations can be made without departing from the spirit of the invention. It is intended that the invention encompass all such modifications and variations as fall within the scope of the appended claims.

What is claimed is:

1. A temperature sensor, comprising:
a current generator module having an input terminal, a first output terminal, and a second output terminal, wherein the current generator module generates a first voltage that is proportional to absolute temperature at the first output terminal and a second voltage that is complementary to absolute temperature at the second output terminal;
a buffer stage having first and second input terminals and an output terminal, the first input terminal coupled to the second output terminal of the current generator module and the output terminal coupled to its second input terminal; and
an amplifier stage having first and second input terminals and an output terminal, the first input terminal coupled to the first output terminal of the current generator module and the second input terminal coupled to the output terminal of the buffer stage.

2. The temperature sensor of claim 1, wherein the amplifier stage is a differential amplifier stage comprising an amplifier having an inverting input terminal, a noninverting input terminal, and an output terminal, and further including a first resistor, wherein the output terminal of the amplifier is coupled to the inverting input terminal through the first resistor.

3. The temperature sensor of claim 2, wherein the differential amplifier stage further includes a second resistor coupled between the inverting input terminal of the amplifier and the second input terminal of the amplifier stage.

4. The temperature sensor of claim 1, wherein the current generator module comprises:
a proportional to absolute temperature generator stage; and
an output stage coupled to the proportional to absolute temperature generator stage.

5. The temperature sensor of claim 4, wherein the proportional to absolute temperature generator stage comprises:
a first transistor having a control electrode and first and second current conducting electrodes;
a second transistor having a control electrode and first and second current conducting electrodes, the control electrodes of the first and second transistors coupled together and the first current conducting electrodes of the first and second transistors coupled together;
a third transistor having a control electrode and first and second current conducting electrodes, the first current carrying electrode of the third transistor coupled to the second current conducting electrode of the first transistor;
a fourth transistor having a control electrode and first and second current conducting electrodes, the control electrodes of the third and fourth transistors coupled together and the second current conducting electrodes of the third and fourth transistors coupled together; and
an impedance coupled between the second current carrying electrode of the second transistor and the first current carrying electrode of the fourth transistor.

6. The temperature sensor of claim 5, wherein the proportional to absolute temperature generator stage further comprises a first amplifier having first and second input terminals and an output terminal, the first input terminal coupled to the second and first current conducting electrodes of the first and third transistors, respectively, the second input terminal coupled to the second current carrying electrode of the second transistor and to the impedance, and the output terminal coupled to the control electrodes of the first and second transistors.

7. The temperature sensor of claim 5, wherein the impedance is a resistor.

8. The temperature sensor of claim 5, wherein the output stage further comprises:
a fifth transistor having a control electrode and first and second current conducting electrodes, the control electrode coupled to the control electrodes of the first and second transistors, the first current conducting electrode coupled to the first current conducting electrodes of the first and second transistors; and
a second impedance having first and second terminals, the first terminal coupled to the second current conducting electrode of the fifth transistor and the second terminal coupled for receiving a first source of operating potential.

9. The temperature sensor of claim 8, wherein the first, second, and third transistors are of a first transistor type and a first conductivity type and the third and fourth transistors are of a second transistor type and the first conductivity type.

10. The temperature sensor of claim 1, wherein the buffer stage comprises a first amplifier having first and second input terminals and an output terminal, the first input terminal of the first amplifier coupled to the second output terminal of the current generator module and the second input terminal coupled to the output terminal of the first amplifier.

11. The temperature sensor of claim 10, wherein the amplifier stage comprises:
a second amplifier having first and second input terminals and an output terminal, the first input terminal of the second amplifier coupled to the first output terminal of the current generator module;
a first impedance having a first terminal coupled to the output terminal of the first amplifier and a second terminal coupled to the second input terminal of the second amplifier; and
a second impedance having a first terminal coupled to the second input terminal of the second amplifier and a second terminal coupled to the output terminal of the second amplifier.

12. The temperature sensor of claim 1, wherein an output voltage of the temperature sensor appearing at the output terminal of the amplifier stage is proportional to a temperature in degrees centigrade.

13. A temperature sensor, comprising:
a delta base-emitter voltage generator circuit having first and second input nodes;
a current mirror having first, second, and third output terminals coupled for transmitting first, second, and third currents, respectively, and wherein the first and second currents are substantially equal and the third current is different from the first and second currents;
a first amplifier having an inverting input terminal, a noninverting input terminal, and an output terminal, the inverting input terminal coupled to the first node and the noninverting input terminal coupled to the second node, wherein a voltage complementary to absolute temperature appears at the first node;
a first impedance coupled to the second node, wherein the second current flows through the first impedance and wherein the second current is proportional to absolute temperature; and
an output stage comprising
a first transistor having a control electrode and first and second current conducting electrodes, the control electrode coupled to the output terminal of the first amplifier and the first current conducting electrode serving as the third output terminal;
a second impedance having first and second terminals, the first terminal coupled to the first current conducting electrode of the first transistor at a third node.

14. The temperature sensor of claim 13, further including:
a second amplifier having an inverting input terminal, a noninverting input terminal, and an output terminal, the noninverting input terminal coupled to the first node; and
a third amplifier having an inverting input terminal, a noninverting input terminal, and an output terminal, the noninverting input terminal coupled to the third node.

15. The temperature sensor of claim 14, wherein the delta base-emitter voltage generator circuit comprises:
a first PNP bipolar transistor having a control electrode and first and second current conducting electrodes;
a second PNP bipolar transistor having a control electrode and first and second current conducting electrodes, the control electrodes and the second current conducting electrodes of the first and second PNP bipolar transistors coupled together and the first current conducting electrode of the first PNP bipolar transistor coupled to the first node; and
a first resistor having a first terminal coupled to the second node and a second terminal coupled to the first current conducting electrode of the second PNP bipolar transistor.

16. The temperature sensor of claim 15, wherein the current mirror comprises:
a second transistor having a control electrode and first and second current conducting electrodes, the first current conducting electrode coupled to the first node;
a third transistor having a control electrode and first and second current conducting electrodes, the first current conducting electrode coupled to the second node; and
the first transistor, the second current conducting electrodes of the first, second, and third transistors coupled together and the control electrodes of the first, second, and third transistors coupled together and to the output terminal of the first amplifier.

17. A method for sensing temperature, comprising:
generating a first voltage that is proportional to absolute temperature by:
maintaining first and second nodes at substantially a second voltage;
using the second voltage to generate a first current through a first resistor;
generating a second current from the first current, wherein the second current flows towards a third node and is proportional to absolute temperature;
using the second current to generate the first voltage at the third node; and
generating a third voltage at the first node, wherein the third voltage is complementary to absolute temperature.

18. The method of claim 17, wherein using the second current to generate the first voltage at the third node includes developing the first voltage across a second resistor.

19. The method of claim 18, wherein using the second current to generate the first voltage further includes generating the first voltage to be proportional to a ratio of a resistance value of the second resistor to a resistance value of the first resistor.

20. The method of claim 17, further including buffering the third voltage to produce a buffered third voltage, wherein the buffered third voltage is complementary to absolute temperature.

21. The method of claim 20, further including generating an output voltage from the buffered third voltage that is complementary to absolute temperature and the first voltage that is proportional to absolute temperature.

22. The method of claim 21, wherein generating the output voltage includes multiplying the buffered third voltage that is complementary to absolute temperature by a gain factor.

23. The method of claim 22, wherein the gain factor comprises a ratio of a resistance value of the third resistor to a resistance value of the second resistor.
